(19) United States
(12) Patent Application Publication
(10) Pub. No.: US 2002/0177245 A1
(43) Pub. Date: Nov. 28, 2002

(54) Method and apparatus for controlling feature critical dimensions based on scatterometry derived profile

(76) Inventors: Thomas J. Sonderman, Austin, TX (US); Christopher A. Bode, Austin, TX (US); Alexander J. Pasadyn, Austin, TX (US); Anthony J. Toprac, Austin, TX (US); Joyce S. Oey Hewett, Austin, TX (US); Anastasia Oshelski Peterson, Austin, TX (US); Michael L. Miller, Cedar Park, TX (US)

Correspondence Address: Scott F. Diring, Patent Agent, Williams, Morgan & Amerson, P.C., Suite 250, 7676 Hillmont, Houston, TX, 77040, US

(21) Appl. No.: 09/821,407

(22) Filed: Mar. 29, 2001

(51) Int. Cl. H01L 21/66

(52) U.S. Cl. 438/14

(57) ABSTRACT

A method for controlling critical dimensions of a feature formed on a semiconductor wafer includes illuminating the wafer; measuring light reflected off the wafer to generate a profile trace; comparing the profile trace to a target profile trace; and modifying an operating recipe of a processing tool used to form the feature based on a deviation between the profile trace and the target profile trace. A processing line includes a processing tool, a scatterometer, and a process controller. The processing tool is adapted to form a feature on a semiconductor wafer in accordance with an operating recipe. The scatterometer is adapted to receive the wafer. The scatterometer includes a light source adapted to illuminate the wafer and a light detector adapted to measure light from the light source reflected off the wafer to generate a profile trace. The process controller is adapted to compare the profile trace to a target profile trace, and modify the operating recipe of the processing tool based on a deviation between the profile trace and the target profile trace.

### BACKGROUND OF THE INVENTION

1. Field of the Invention

This invention relates generally to controlling a semiconductor device manufacturing process and, more particularly, to a method and apparatus for controlling the critical dimensions of a feature based on a feature profile derived from scatterometry measurements.

2. Description of the Related Art

Semiconductor integrated circuit devices are employed in numerous applications, including microprocessors. Generally, the performance of a semiconductor device is dependent on both the density and the speed of the devices formed therein. A common element of a semiconductor device that has a great impact on its performance is a transistor. Design features, such as gate length and channel length, are being steadily decreased in order to achieve higher package densities and to improve device performance. The rapid advance of field effect transistor design has affected a large variety of activities in the field of electronics in which the transistors are operated in a binary switching mode. In particular, complex digital circuits, such as microprocessors and the like, demand fast-switching transistors. Accordingly, the distance between the drain region and the source region of a field effect transistor, commonly referred to as the channel length or gate length dimension, has been reduced to accelerate the formation of a conductive channel between a source and a drain electrode as soon as a switching gate voltage is applied and, moreover, to reduce the electrical resistance of the channel.

In modern transistor structures the longitudinal dimension of the transistor, commonly referred to as the width dimension, extends up to approximately 20 μm, whereas the distance of the drain and source, i.e., the gate length, may be reduced down to approximately 0.2 μm or less. As the gate length of the channel has been reduced to obtain the desired switching characteristic of the source-drain line, the length of the gate electrode has also reduced. Since the gate electrode is typically contacted at one end of its structure, the electrical charges have to be transported along the entire width of the gate electrode, i.e, up to 20 μm, to uniformly build up the transverse electric field that is necessary for forming the channel between the source and drain regions. Due to the small length of the gate electrode, which usually consists of a doped polycrystalline silicon, the electrical resistance of the gate electrode is relatively high, and it may cause high RC-delay time constants. Hence, the transverse electrical field necessary for fully opening the channel is delayed, thereby further deteriorating the switching time of the transistor. As a consequence, the rise and fall times of the electrical signals are increased, and the maximum operating frequency, i. e., the clock frequency, is limited by the signal performance.

In view of the foregoing, the control of the critical dimensions of the gate electrode is an increasingly important element of the fabrication process. If a gate electrode is formed overly large, its switching speed is compromised. On the other hand, if the gate electrode is formed too small, based on the design characteristics of the adjacent dielectric materials, the transistor will exhibit a higher leakage current, causing an excessive power usage and heat generation. Hence, its is important to control critical dimensions of a gate electrode such that the variation around a target gate electrode value is minimized.

Typically, a gate electrode does not have a consistent profile along its length and height. The profile of a gate electrode affects its performance. Various factors in the fabrication process affect the slope of the sidewall, including photolithography and etch parameters. The critical dimensions of a gate electrode affecting its performance include not only its average length, but also its profile.

FIG. 1 illustrates a profile of a typical gate electrode stack 10 (i.e., including a gate electrode formed over a gate insulation layer) used in forming a transistor. Typically, the gate electrode stack 10 has a faceted corner 12, a sloped sidewall 14, and a notch 16. Hence, the gate electrode stack 10 has a top length 18, a middle length 20, and a bottom length 22. The bottom length 22 determines the spacing of subsequently formed source and drain active regions, and thus, affects the channel length of the transistor formed. However, the other dimensions also affect the performance of the device. Typically, gate electrode profiles are measured using a destructive metrology method, whereby a wafer is cut to generate a cross section. The cross section is analyzed with a scanning electron microscope to determine the dimensions of the gate electrode stack. The analysis procedure is expensive as the tested wafer must be scrapped. Also, because the metrology process is time consuming, it is not practical to use the metrology information for real-time process control of the gate formation process.

The present invention is directed to overcoming, or at least reducing the effects of, one or more of the problems set forth above.

### SUMMARY OF THE INVENTION

One aspect of the present invention is seen in a method for controlling critical dimensions of a feature formed on a semiconductor wafer. The method includes illuminating the wafer; measuring light reflected off the wafer to generate a profile trace; comparing the profile trace to a target profile trace; and modifying an operating recipe of a processing tool used to form the feature based on a deviation between the profile trace and the target profile trace.

Another aspect of the present invention is seen in a processing line including a processing tool, a scatterometer, and a process controller. The processing tool is adapted to form a feature on a semiconductor wafer in accordance with an operating recipe. The scatterometer is adapted to receive the wafer. The scatterometer includes a light source adapted to illuminate the wafer and a light detector adapted to measure light from the light source reflected off the wafer to generate a profile trace. The process controller is adapted to compare the profile trace to a target profile trace, and modify the operating recipe of the processing tool based on a deviation between the profile trace and the target profile trace.

### BRIEF DESCRIPTION OF THE DRAWINGS

The invention may be understood by reference to the following description taken in conjunction with the accompanying drawings, in which like reference numerals identify like elements, and in which:

FIG. 1 is cross-section view of a prior art gate electrode stack;

FIG. 2 is a simplified block diagram of a processing line in accordance with one illustrative embodiment of the present invention;

FIG. 3 is a simplified diagram of a scatterometer in the processing line of FIG. 2; and

FIG. 4 is a simplified flow diagram of a method for controlling critical dimensions based on a feature profile derived from scatterometry measurements in accordance with another illustrative embodiment of the present invention.

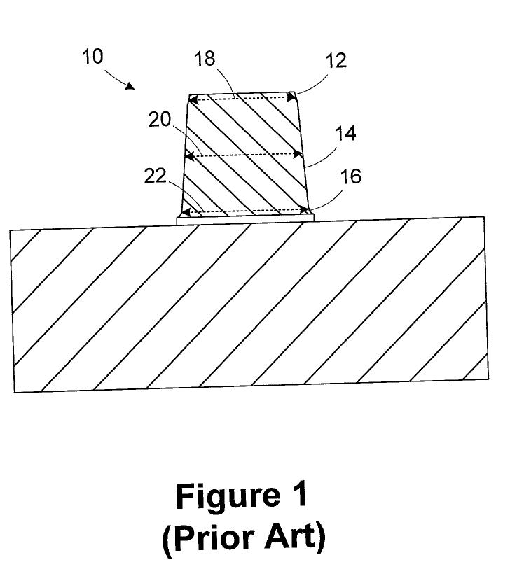

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

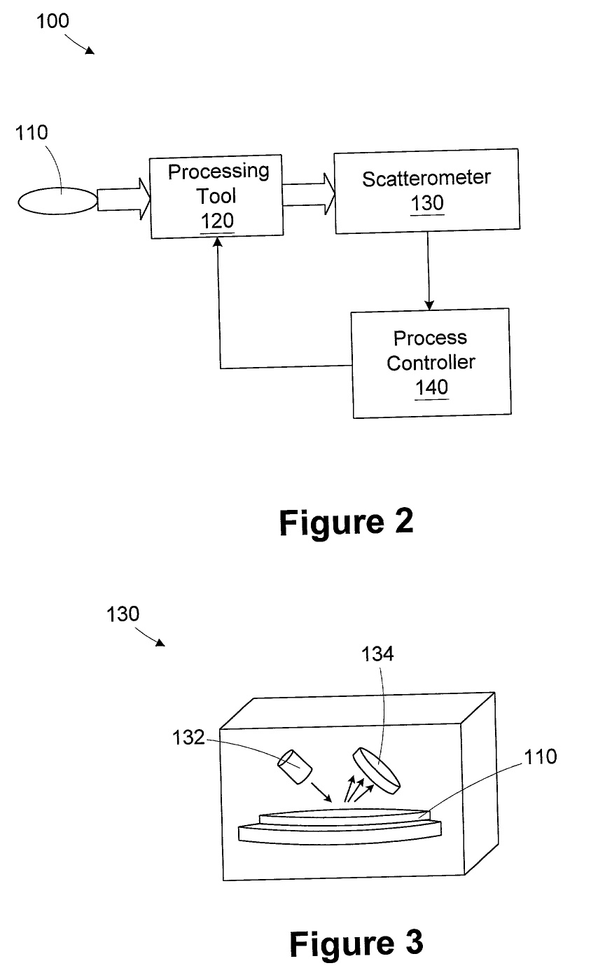

Referring now to FIG. 2, a simplified diagram of a portion of an illustrative processing line 100 for processing wafers 110 in accordance with the present invention is provided. The processing line 100 includes a processing tool 120, a scatterometer 130, and a process controller 140. The processing line 100 may be used to form features, such as gate electrodes, on the wafers 110. For clarity and ease of illustration, not all of the tools and process steps required for forming the features are shown.

Typically, the formation of features requires at least one patterning step, where a photoresist layer is deposited over a process layer by spinning on the photoresist layer in a photoresist coating tool, commonly referred to as a track. In the case where a gate electrode is being formed, the process layer may be a doped polysilicon layer. In the case where a trench is being formed (e.g., for isolation structure or interconnect structures), the process layer may be a dielectric later, such as silicon dioxide. The photoresist layer is subsequently exposed to form a pattern therein. Depending on the specific photoresist material used, the exposed photoresist may also be subjected to a post exposure bake process to complete the patterning process (e.g., for a chemically amplified resist). Following the exposure and/or bake a developer solution is applied to remove the exposed portions of the photoresist (i.e., for a negative type photoresist).

The patterned photoresist layer is used as a mask to define the regions where the features are to be formed. Subsequently, an etching step is performed in an etch tool to remove portions of the process layer exposed through the mask. As described in greater detail below, certain parameters in the operating recipes of the various tools affect the profiles (e.g., sidewall angle) of the features being formed.

The scatterometer 130 determines the profile of the features (e.g., gate electrode stacks or trenches) formed on the wafer 110 through a correlation process and provides profile information to the process controller 140. The process controller 140, based on the profile information, may change the operating recipe of the processing tool 120 to adjust the profile for subsequent wafers 110 such that it is closer to a target profile. As described in greater detail below, the particular process performed by the processing tool 120 depends on the particular process variable or variables being controlled.

Turning briefly to FIG. 3, the scatterometer 130 includes a light source 132 and a detector 134 positioned proximate the wafer 110. The light source 132 of the scatterometer 130 illuminates at least a portion of the wafer 110, and the detector 134 takes optical measurements, such as intensity, of the reflected light. Although the invention is described using a scatterometer 130 designed to measure reflected light intensity, the invention is not so limited, as other measurement tools, such as an ellipsometer, a reflectometer, a spectrometer, or some other light measuring device may be used. The scatterometer 130 may use monochromatic light, white light, or some other wavelength or combinations of wavelengths, depending on the specific implementation. The angle of incidence of the light may also vary, depending on the specific implementation. For example, the light source 132 and the detector 134 may be arranged in a concentric circle configuration, with the light source 132 illuminating the wafer 110 from a perpendicular orientation. The profiles of the features formed on the wafer 110 affects the manner in which light is reflected from the light source 132.

The scatterometer 130 is adapted to generate a profile trace for a wafer 110 with features formed thereon. The scatterometer 130 may sample one or more wafers in a lot or even generate a profile trace for each wafer in the lot, depending on the specific implementation. For example, the traces from a sample of the wafers 110 in a lot may be averaged. The process controller 140 compares the current profile trace (i.e., individual or averaged) generated by the scatterometer 130 to a library of historical profile traces with known feature profiles to correlate the current profile trace to an expected feature profile. The library of historical profile traces may be generated from previous destructive metrology tests, where a scatterometry profile trace is measured and the actual profile of the features is subsequently measured using a cross sectional scanning electron microscope metrology technique.

The correlation between the scatterometry profile trace and the actual feature profile is dependent on various factors, including the type of photoresist used, the underlying process layer, the particular process used to form the feature, and the particular tools used to perform the processing steps. For each unique process, a separate library of historical scatterometry profile traces may be generated.

Based on the correlated feature profile determined by the process controller 140, control equations may be employed to adjust the operating recipe of the processing tool 120 to account for deviations in the correlated feature profile from a target feature profile. The control equations may be developed empirically using commonly known linear or non-linear techniques. The process controller 140 may automatically control the operating recipes of one or more of the processing tools 120 used to form the features on the wafers 110. The deviations between the profiles of subsequently processed wafers 110 and a target profile can be reduced. The following examples illustrate how the various recipes may be modified to control the critical dimensions based on the scatterometry derived profile information.

Table 1 below illustrates the particular tools that may be controlled by the process controller 140 to affect the critical dimensions of the features formed on the wafer.

TABLE 1

| | | Effect |
|---|---|---|
| Processing Tool | Variable(s) Controlled | on Critical Dimensions |
| Photoresist Coating | Spin Speed | Each variable affects the |
| Tool | Temperature | final thickness of the |
| | Time | photoresist layer, which |
| | | impacts the linewidth based |
| | | on the swing curve. |
| Stepper | Focus | Sidewall angle |
| | Exposure Energy | Linewidth, sidewall angle |
| Developer | Time | Linewidth, sidewall angle |
| | Flow Rate | Linewidth, sidewall angle |
| Post Exposure Bake | Time | Linewidth |
| Tool | Temperature | |
| Etch Tool | Etch Time | Etch depth, CD if |
| | | isotropic |
| | Process Gas Flow Rate | Anisotropy-linewidth |
| | Plasma Power | Anisotropy-linewidth |
| | Temperature | Footing, beveling |
| | Pressure | Anisotropy-linewidth |

Changes to process variables, such as those described above, that affect profile often have an impact on the critical dimensions. Accordingly, critical dimension control is considered when process changes for controlling profile are made.

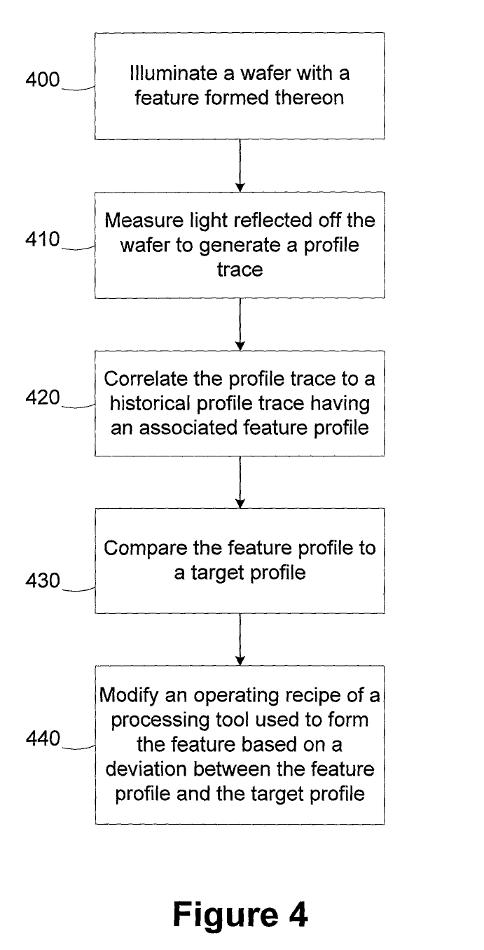

Turning now to FIG. 4, a simplified flow diagram of a method for controlling critical dimensions based on a feature profile derived from scatterometry measurements in accordance with another illustrative embodiment of the present invention is provided. In block 400, a wafer is illuminated. In block 410, light reflected off the wafer is measured to generate a profile trace. The profile trace is correlated to a historical profile trace in block 420. The historical profile trace has an associated feature profile. In block 430, the feature profile is compared to a target profile. In block 440, the operating recipe of a processing tool used to form the feature is modified based on a deviation between the feature profile and the target profile.

By adjusting the operating recipe(s) of the processing tool(s) used to form the features on the wafer, as described above, the resultant profiles can be adjusted to reduce the overall profile variations in the processing line 100. Reduced variation equates directly to reduced process cost, increased device performance, and increased profitability.

In another embodiment of the present invention, the scatterometry measurements may be used to identify a problem condition with the processing tool 120. The processing tool 120 may have a degraded condition preventing it from effectively performing its processing task. The scatterometry measurements taken for the current profile trace may be compared to a baseline scatterometry trace for the processing tool 120 taken while the processing tool 120 is known to be operating in a good state (i.e., known good state profile). If the current profile trace differs significantly from the known good state profile, a fault condition with the processing tool 120 may be present. A control limit technique may be implemented by the process controller 140 to identify the fault condition. For example, if the current profile correlates to a feature profile having a dimension more than a predetermined amount from a target dimension, a fault condition may be signaled. In another variation, if the process controller 140 fails to find an adequate correlation between the current profile and one of the profiles in the library of historical profile traces, a fault condition may be signaled.

Upon identifying a potential fault with the processing tool 120, the process controller 140 may take a variety of corrective actions. For example, the process controller may trigger a local alarm or signal light and prevent further operation of the processing tool 120. The process controller 140 may be coupled to a centralized communication system such as a network for communicating with other devices. The process controller 140 may be programmed to send an e-mail message to a designated operator of the processing tool 120. The process controller 140 may also send a message through the network to a centralized facility management system (not shown) to identify the degraded condition, and log the processing tool 120 out of service until a corrective action can be taken.

In essence the process controller 140 operates in both a control mode and a monitoring mode. By comparing the profile trace to a target profile trace and modifying the operating recipe of the processing tool 120 to account for variations in the processing of the processing tool 120, the process controller 140 reduces the variation in the processing line 10. By comparing the profile trace to a known good state profile, the process controller 140 may identify problem or fault conditions with the processing tool 120. The target profile trace may be the same as the known good state profile, with the difference in response depending one the magnitude of the deviation between the current profile and the target profile. Relatively small deviations may be addressed by control of the operating recipe, and larger deviations may be addressed by taking the processing tool 120 out of service.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method for controlling critical dimensions of a feature formed on a semiconductor wafer, comprising:
illuminating the wafer;
measuring light reflected off the wafer to generate a profile trace;
comparing the profile trace to a target profile trace; and
modifying an operating recipe of a processing tool used to form the feature based on a deviation between the profile trace and the target profile trace.

2. The method of claim 1, further comprising:
correlating the profile trace to a historical profile trace, the historical profile trace having an associated feature profile; and
comparing the feature profile to a target profile.

3. The method of claim 2, further comprising modifying the operating recipe of the processing tool based on a deviation between the feature profile and the target profile.

4. The method of claim 1, wherein measuring the reflected light includes measuring the intensity of the reflected light.

5. The method of claim 1, further comprising providing a library of historical profile traces.

6. The method of claim 1, further comprising:
generating a plurality of profile traces for a plurality of wafers;
averaging the plurality of profile traces to generate an average profile trace; and
comparing the average profile trace to a historical profile trace.

7. The method of claim 1, further comprising identifying a fault condition associated with the processing tool based on the deviation between the profile trace and the target profile trace.

8. The method of claim 7, further comprising preventing further operation of the processing tool in response to identifying the fault condition.

9. The method of claim 1, wherein the process tool comprises a photoresist coating tool, and modifying the operating recipe comprises modifying at least one of a spin speed, a temperature, and a time control variable.

10. The method of claim 1, wherein the process tool comprises a photolithography stepper, and modifying the operating recipe comprises modifying at least one of a focus and a exposure energy control variable.

11. The method of claim 1, wherein the process tool comprises a developer, and modifying the operating recipe comprises modifying at least one of a time and a flow rate control variable.

12. The method of claim 1, wherein the process tool comprises a post exposure bake tool, and modifying the operating recipe comprises modifying at least one of a time and a temperature control variable.

13. The method of claim 1, wherein the process tool comprises an etch tool, and modifying the operating recipe comprises modifying at least one of an etch time, a process gas flow rate, a plasma power, a temperature, and a pressure control variable.

14. A processing line, comprising:
a processing tool for forming a feature on a semiconductor wafer in accordance with an operating recipe;
a scatterometer adapted to receive the wafer, the scatterometer comprising:
a light source adapted to illuminate the wafer; and
a light detector adapted to measure light from the light source reflected off the wafer to generate a profile trace; and
a process controller adapted to compare the profile trace to a target profile trace, and modify the operating recipe of the processing tool based on a deviation between the profile trace and the target profile trace.

15. The processing line of claim 14, wherein the process controller is further adapted to correlate the profile trace to a historical profile trace, the historical profile trace having an associated feature profile, and compare the feature profile to a target profile.

16. The processing line of claim 15, wherein the process controller is further adapted to modify the operating recipe of the processing tool based on a deviation between the feature profile and the target profile.

17. The processing line of claim 14, wherein the light detector is. adapted to measure the intensity of the reflected light.

18. The processing line of claim 14, wherein the process controller is adapted to store a library of historical profile traces.

19. The processing line of claim 14, wherein the processing tool is adapted to form features on a plurality of semiconductor wafers, the scatterometer is adapted to generate a plurality of profile traces for the plurality of wafers, and the process controller is adapted to average the plurality of profile traces to generate an average profile trace and compare the average profile trace to a historical profile trace.

20. The processing line of claim 14, wherein the process controller is further adapted to identify a fault condition associated with the processing tool based on the deviation between the profile trace and the target profile trace.

21. The processing line of claim 20, wherein the process controller is further adapted to prevent further operation of the processing tool in response to identifying the fault condition.

22. The processing line of claim 14, wherein the processing tool comprises a photoresist coating tool, and the process controller is adapted to modify at least one of a spin speed, a temperature, and a time control variable.

23. The processing line of claim 14, wherein the processing tool comprises a photolithography stepper, and the process controller is adapted to modify at least one of a focus and a exposure energy control variable.

24. The processing line of claim 14, wherein the process tool comprises a developer, and the process controller is adapted to modify at least one of a time and a flow rate control variable.

25. The processing line of claim 14, wherein the process tool comprises a post exposure bake tool, and the process controller is adapted to modify at least one of a time and a temperature control variable.

26. The processing line of claim 14, wherein the process tool comprises an etch tool, and the process controller is adapted to modify at least one of an etch time, a process gas flow rate, a plasma power, a temperature, and a pressure control variable.

27. A processing line comprising:
means for forming a feature on a semiconductor wafer in accordance with an operating recipe;
means for illuminating the wafer;
means for measuring light from the illuminating means reflected off the wafer to generate a profile trace;
means for correlating the profile trace to a historical profile trace, the historical profile trace having an associated feature profile;
means for comparing the profile trace to a target profile trace; and
means for modifying the operating recipe based on a deviation between the profile trace and the target profile trace.
